(19) United States
(12) Patent Application Publication
(10) Pub. No.: US 2025/0040373 A1
(43) Pub. Date: Jan. 30, 2025

(54) DISPLAY DEVICE AND MANUFACTURING METHOD THEREOF

(71) Applicant: Japan Display Inc., Tokyo (JP)

(72) Inventor: Sho YANAGISAWA, Tokyo (JP)

(73) Assignee: Japan Display Inc., Tokyo (JP)

(21) Appl. No.: 18/770,692

(22) Filed: Jul. 12, 2024

(30) Foreign Application Priority Data
Jul. 28, 2023 (JP) 2023-123285

(51) Int. Cl. H10K 59/131; H10K 59/12; H10K 59/80; H10K 71/16; H10K 77/10

(52) U.S. Cl. CPC H10K 59/131; H10K 59/1201; H10K 59/871; H10K 71/166; H10K 77/111

(57) ABSTRACT

According to one embodiment, a display device includes a resinous substrate having flexibility, a circuit layer including a plurality of insulating layers provided over a display area and a surrounding area, a first organic insulating layer provided on the circuit layer, a first inorganic insulating layer provided on the first organic insulating layer, and a first partition including a first lower portion provided on the first inorganic insulating layer and a first upper portion which is provided on the first lower portion and protrudes from a side surface of the lower portion. The circuit layer has a belt-like area in which at least one of the plurality of insulating layers is lost in a belt-like shape. The first partition is provided in the belt-like area.

### CROSS-REFERENCE TO RELATED APPLICATION

This application is based upon and claims the benefit of priority from Japanese Patent Application No. 2023-123285, filed Jul. 28, 2023, the entire contents of which are incorporated herein by reference.

### FIELD

Embodiments described herein relate generally to a display device and a manufacturing method thereof.

### BACKGROUND

Recently, display devices to which an organic light emitting diode (OLED) is applied as a display element have been put into practical use. This display element comprises a pixel circuit including a thin-film transistor, a lower electrode connected to the pixel circuit, an organic layer which covers the lower electrode, and an upper electrode which covers the organic layer.

In the process of manufacturing such a display element, a technique which prevents the reduction in reliability has been required.

### BRIEF DESCRIPTION OF THE DRAWINGS

FIG. 1 is a plan view showing a configuration example of a display device DSP.

FIG. 2 is a perspective view showing a state in which the display panel PNL shown in FIG. 1 is bent.

FIG. 3 is a plan view showing another configuration example of the display device DSP.

FIG. 4 is a perspective view showing a state in which the display panel PNL shown in FIG. 3 is bent.

FIG. 5 is a plan view showing another configuration example of the display device DSP.

FIG. 6 is a perspective view showing a state in which the display panel PNL shown in FIG. 5 is bent.

FIG. 7 is a diagram showing an example of the layout of subpixels SP1, SP2 and SP3.

FIG. 8 is a schematic cross-sectional view of the display device DSP along the A-B line of FIG. 7.

FIG. 9A is a plan view showing an example of the shape of a partition 7.

FIG. 9B is a plan view showing another example of the shape of the partition 7.

FIG. 9C is a plan view showing another example of the shape of the partition 7.

FIG. 10 is a cross-sectional view of the display device DSP along the partition 7 intersecting with a belt-like area BA.

FIG. 11 is a cross-sectional view of the display device DSP along the C-D line of FIG. 9.

FIG. 12 is a cross-sectional view of the display device DSP including a metal line ML intersecting with the belt-like area BA

FIG. 13 is a diagram for explaining the manufacturing method of the display device DSP.

FIG. 14A is a diagram for explaining the manufacturing method of the display device DSP.

FIG. 14B is a diagram for explaining the manufacturing method of the display device DSP.

FIG. 15A is a diagram for explaining the manufacturing method of the display device DSP.

FIG. 15B is a diagram for explaining the manufacturing method of the display device DSP.

FIG. 16A is a diagram for explaining the manufacturing method of the display device DSP.

FIG. 16B is a diagram for explaining the manufacturing method of the display device DSP.

FIG. 17 is a diagram for explaining the manufacturing method of the display device DSP.

FIG. 18 is a diagram for explaining the manufacturing method of the display device DSP.

FIG. 19 is a diagram for explaining the manufacturing method of the display device DSP.

FIG. 20 is a cross-sectional view for explaining a state in which a stacked film FL1 is formed in the belt-like area BA.

### DETAILED DESCRIPTION

Embodiments described herein aim to provide a display device and a manufacturing method thereof such that the reduction in reliability can be prevented.

In general, according to one embodiment, a display device comprises a resinous substrate having flexibility, a circuit layer including a plurality of insulating layers provided over a display area which displays an image and a surrounding area located on an external side relative to the display area on the resinous substrate, a first organic insulating layer provided over the display area and the surrounding area on the circuit layer, a first inorganic insulating layer provided over the display area and the surrounding area on the first organic insulating layer, and a first partition comprising a first lower portion provided on the first inorganic insulating layer and a first upper portion which is provided on the first lower portion and protrudes from a side surface of the first lower portion in the surrounding area. The circuit layer has a belt-like area in which at least one of the plurality of insulating layers is lost in a belt-like shape. The first partition is provided in the belt-like area.

According to another embodiment, a display device comprises a display panel which comprises a display area displaying an image and a surrounding area located on an external side relative to the display area and which is bent in a belt-like area. The display panel comprises a resinous substrate having flexibility, a first organic insulating layer provided over the display area and the surrounding area above the resinous substrate, a first inorganic insulating layer provided over the display area and the surrounding area on the first organic insulating layer, and a first partition comprising a first lower portion provided on the first inorganic insulating layer and a first upper portion which is provided on the first lower portion and protrudes from a side surface of the first lower portion in the belt-like area.

According to yet another embodiment, a manufacturing method of a display device comprises forming a circuit layer including a plurality of insulating layers over a display area which displays an image and a surrounding area located on an external side relative to the display area on a resinous substrate having flexibility, forming a first organic insulating layer over the display area and the surrounding area on the circuit layer, forming a first inorganic insulating layer over the display area and the surrounding area on the first organic insulating layer, and forming a first partition having a first lower portion located on the first inorganic insulating layer and a first upper portion which is located on the first lower portion and protrudes from a side surface of the first lower portion in the surrounding area. The circuit layer has a belt-like area in which at least one of the plurality of insulating layers is lost in a belt-like shape. The first partition is located in the belt-like area.

The embodiments can provide a display device and a manufacturing method thereof such that the reduction in reliability can be prevented.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. When various types of elements are viewed parallel to the third direction Z, the appearance is defined as a plan view.

The display device of the present embodiment is an organic electroluminescent display device comprising an organic light emitting diode (OLED) as a display element, and could be mounted on a television, a personal computer, a vehicle-mounted device, a tablet, a smartphone, a mobile phone, etc.

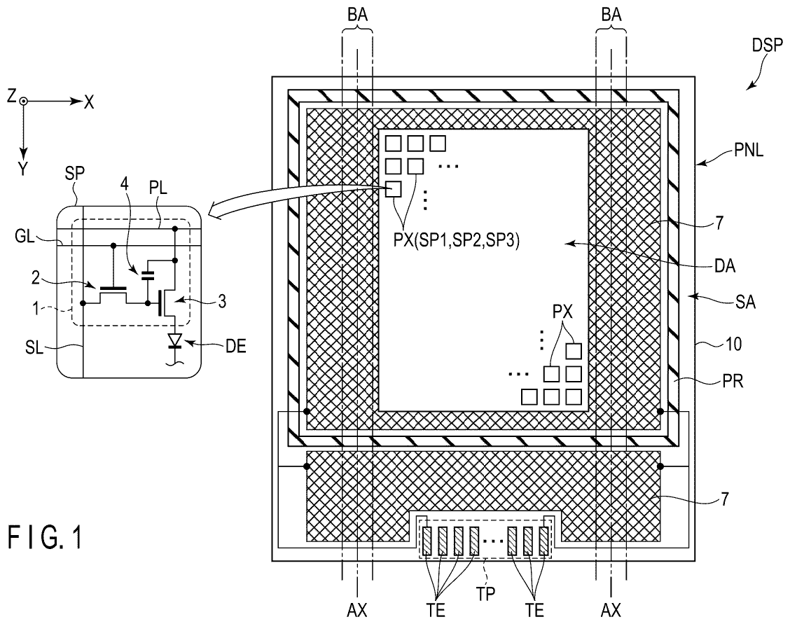

FIG. 1 is a plan view showing a configuration example of a display device DSP.

The display device DSP comprises a display panel PNL having a display area DA which displays an image and a surrounding area SA located on an external side relative to the display area DA on an insulating substrate 10. The substrate 10 is a resinous substrate having flexibility.

In the present embodiment, the substrate 10 is rectangular in plan view. It should be noted that the shape of the substrate 10 in plan view is not limited to a rectangle and may be another shape such as a square, a circle or an oval.

The display area DA comprises a plurality of pixels PX arrayed in matrix in a first direction X and a second direction Y. Each pixel PX includes a plurality of subpixels SP. For example, each pixel PX includes subpixel SP1 which exhibits a first color, subpixel SP2 which exhibits a second color and subpixel SP3 which exhibits a third color. The first color, the second color and the third color are different colors. Each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element DE driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the anode of the display element DE.

It should be noted that the configuration of the pixel circuit 1 is not limited to the example shown in the figure. For example, the pixel circuit 1 may comprise more thin-film transistors and capacitors.

The display element DE is an organic light emitting diode (OLED) as a light emitting element, and may be called an organic EL element.

The surrounding area SA has a terminal portion TP, a convex portion PR and a partition 7.

The terminal portion TP includes a plurality of terminals TE which are unidirectionally arranged. In the example shown in the figure, the terminals TE are arranged in the first direction X. Each of the terminals TE extends in the second direction Y. However, the configuration is not limited to this example. For example, some of the terminals TE may extend in an oblique direction. For example, these terminals TE are electrically connected to a flexible printed circuit or an IC chip.

The convex portion PR is formed into a frame-like shape which surrounds the display area DA. This convex portion PR is formed by using an organic insulating layer provided in the display area DA.

The partition 7 is provided between the display area DA and the convex portion PR and outside the convex portion PR. This partition 7 may be formed into various shapes such as a grating shape, a linear shape, a curved shape, the shape of broken lines and an island-like shape. The partition 7 is conductive and is electrically connected to each terminal TE having a common potential. This configuration can prevent an electrostatic discharge failure in the manufacturing process at a position where the partition 7 is adjacent to a conductive layer (including another partition) compared to a case where the partition 7 having a large area is electrically floating.

The specific shape of the partition 7 is described in detail later.

This display panel PNL has belt-like areas BA. In the example shown in the figure, the two belt-like areas BA are located in the surrounding area SA, and both of them extend in the second direction Y. The display area DA and the terminal portion TP are located between the two belt-like areas BA. Each of these belt-like areas BA is an area which can be bent based on axis AX parallel to the second direction Y. The partition 7 is provided in the belt-like areas BA as well.

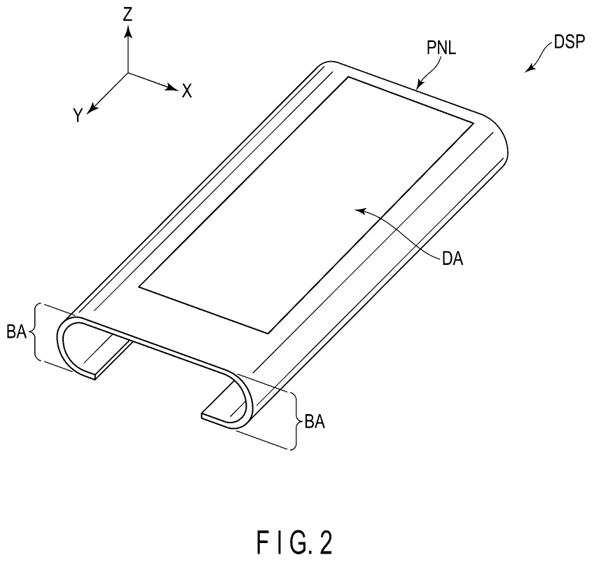

FIG. 2 is a perspective view showing a state in which the display panel PNL shown in FIG. 1 is bent.

The belt-like areas BA are curved. In the display panel PNL, areas located on the external side of the belt-like areas BA (or areas located on a side opposite to the display area DA across the intervening belt-like areas BA) are arranged on the back surface side of the display area DA. Since the display panel PNL is bent in the belt-like areas BA in this manner, in the display device DSP, the width parallel to the first direction X around the display area DA can be reduced, thereby realizing the reduction in the width of the frame.

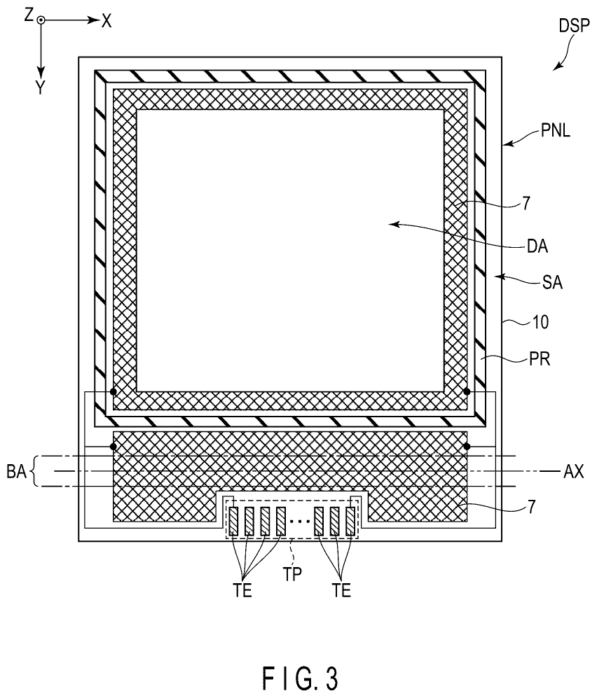

FIG. 3 is a plan view showing another configuration example of the display device DSP.

The configuration example shown in FIG. 3 is different from that shown in FIG. 1 in respect that the belt-like area BA extends in the first direction X. In the example shown in the figure, the belt-like area BA is located between the display area DA and the terminal portion TP in the surrounding area SA. This belt-like area BA is an area which can be bent based on axis AX parallel to the first direction X. The partition 7 is provided in the surrounding area SA including the belt-like area BA.

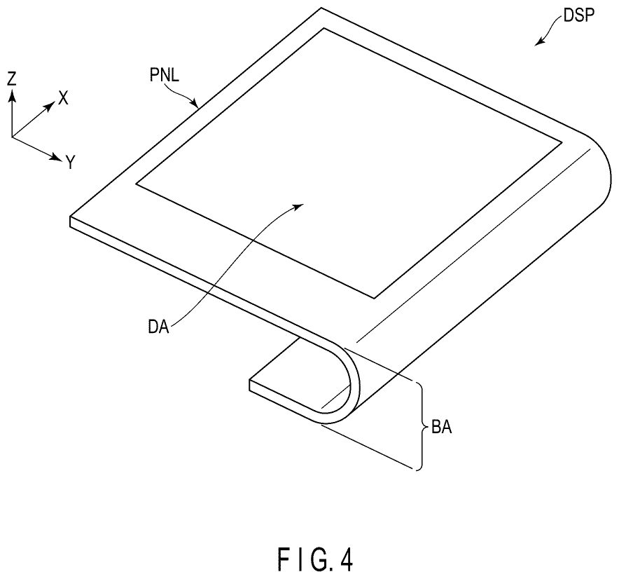

FIG. 4 is a perspective view showing a state in which the display panel PNL shown in FIG. 3 is bent.

The belt-like area BA is curved. In the display panel PNL, an area located on a side opposite to the display area DA across the intervening belt-like area BA is arranged on the back surface side of the display area DA. Since the display panel PNL is bent in the belt-like area BA in this manner, in the display device DSP, the width parallel to the second direction Y around the display area DA can be reduced, thereby realizing the reduction in the width of the frame.

FIG. 5 is a plan view showing another configuration example of the display device DSP.

The configuration example shown in FIG. 5 is different from that shown in FIG. 1 in respect that the belt-like area BA is located in the surrounding area SA and intersects with the display area DA. In the example shown in the figure, the belt-like area BA is located between two terminal portions TP in the surrounding area SA. This belt-like area BA is an area which can be bent based on axis AX parallel to the second direction Y. The partition 7 is provided in the surrounding area SA including the belt-like area BA.

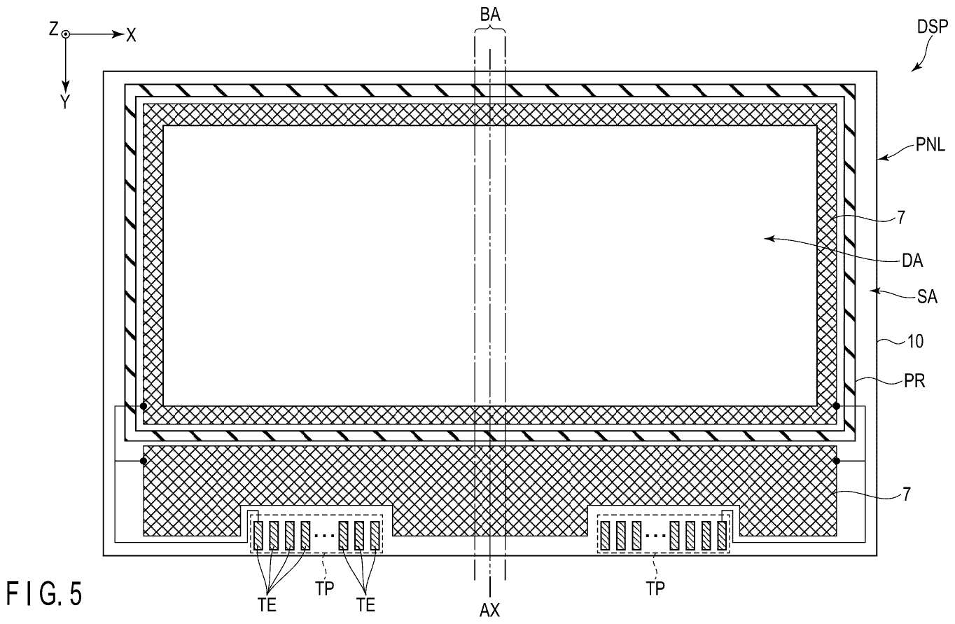

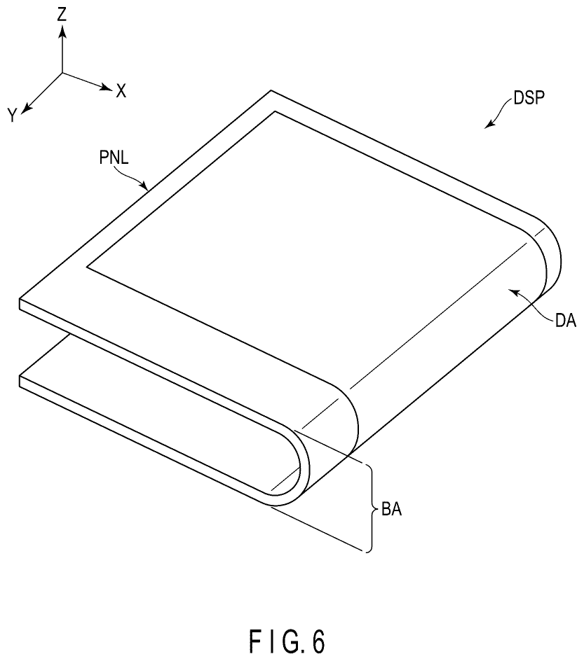

FIG. 6 is a perspective view showing a state in which the display panel PNL shown in FIG. 5 is bent.

The belt-like area BA is curved. In this manner, the display panel PNL can be bent in the belt-like area BA intersecting with the display area DA. Thus, the display device DSP which can be folded can be provided.

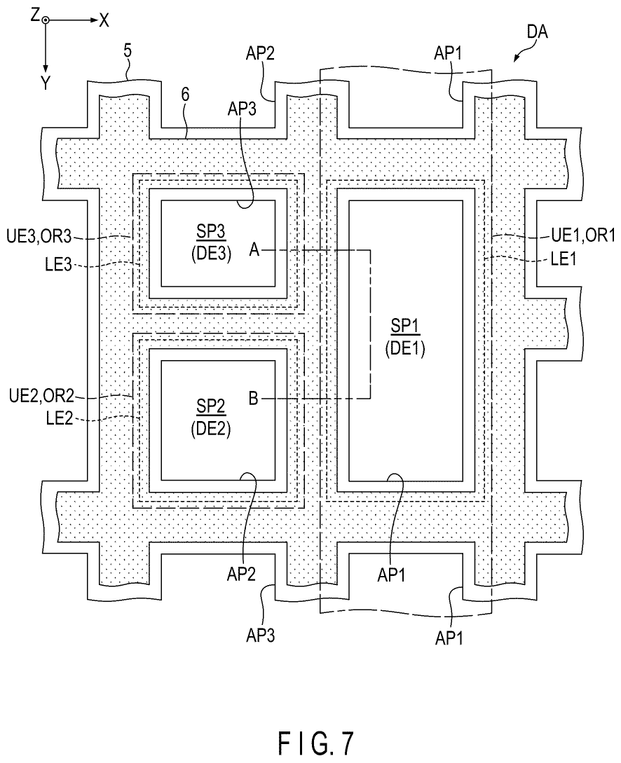

FIG. 7 is a diagram showing an example of the layout of subpixels SP1, SP2 and SP3.

In the example shown in the figure, subpixels SP2 and SP3 are arranged in the second direction Y. Subpixels SP1 and SP2 are arranged in the first direction X, and subpixels SP1 and SP3 are arranged in the first direction X.

When subpixels SP1, SP2 and SP3 are provided in line with this layout, a column in which subpixels SP2 and SP3 are alternately provided in the second direction Y and a column in which a plurality of subpixels SP1 are provided in the second direction Y are formed in the display area DA. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

An insulating layer 5 and a partition 6 are provided in the display area DA. The insulating layer 5 has apertures AP1, AP2 and AP3 in subpixels SP1, SP2 and SP3, respectively. The insulating layer 5 having these apertures AP1, AP2 and AP3 may be called a rib.

The partition 6 overlaps the insulating layer 5 in plan view. The partition 6 is formed into a grating shape surrounding the apertures AP1, AP2 and AP3. In other words, the partition 6 has apertures in subpixels SP1, SP2 and SP3 in a manner similar to that of the insulating layer 5. The partition 6 is conductive and is electrically connected to the partition 7 shown in FIG. 1 and each terminal TE having a common potential.

Subpixels SP1, SP2 and SP3 comprise display elements DE1, DE2 and DE3, respectively, as the display elements DE.

The display element DE1 of subpixel SP1 comprises a lower electrode LE1, an upper electrode UE1 and an organic layer OR1 overlapping the aperture AP1. The lower electrode LE1, the organic layer OR1 and the upper electrode UE1 are surrounded by the partition 6 in plan view. The peripheral portion of each of the lower electrode LE1, the organic layer OR1 and the upper electrode UE1 overlaps the insulating layer 5 in plan view.

The display element DE2 of subpixel SP2 comprises a lower electrode LE2, an upper electrode UE2 and an organic layer OR2 overlapping the aperture AP2. The lower electrode LE2, the organic layer OR2 and the upper electrode UE2 are surrounded by the partition 6 in plan view. The peripheral portion of each of the lower electrode LE2, the organic layer OR2 and the upper electrode UE2 overlaps the insulating layer 5 in plan view.

The display element DE3 of subpixel SP3 comprises a lower electrode LE3, an upper electrode UE3 and an organic layer OR3 overlapping the aperture AP3. The lower electrode LE3, the organic layer OR3 and the upper electrode UE3 are surrounded by the partition 6 in plan view. The peripheral portion of each of the lower electrode LE3, the organic layer OR3 and the upper electrode UE3 overlaps the insulating layer 5 in plan view.

In the example shown in the figure, the outer shapes of the lower electrodes LE1, LE2 and LE3 are shown by broken lines, and the outer shapes of the organic layers OR1, OR2 and OR3 and the upper electrodes UE1, UE2 and UE3 are shown by alternate long and short dash lines. It should be noted that the outer shape of each of the lower electrodes, organic layers and upper electrodes shown in the figure does not necessarily reflect the accurate shape.

The lower electrodes LE1, LE2 and LE3 correspond to, for example, the anodes of the display elements. The upper electrodes UE1, UE2 and UE3 correspond to the cathodes of the display elements or a common electrode and are in contact with the partition 6.

In the example shown in the figure, the area of the aperture AP1, the area of the aperture AP2 and the area of the aperture AP3 are different from each other. The area of the aperture AP1 is greater than that of the aperture AP2, and the area of the aperture AP2 is greater than that of the aperture AP3. In other words, the area of the lower electrode LE1 exposed from the aperture AP1 is greater than that of the lower electrode LE2 exposed from the aperture AP2. The area of the lower electrode LE2 exposed from the aperture AP2 is greater than that of the lower electrode LE3 exposed from the aperture AP3.

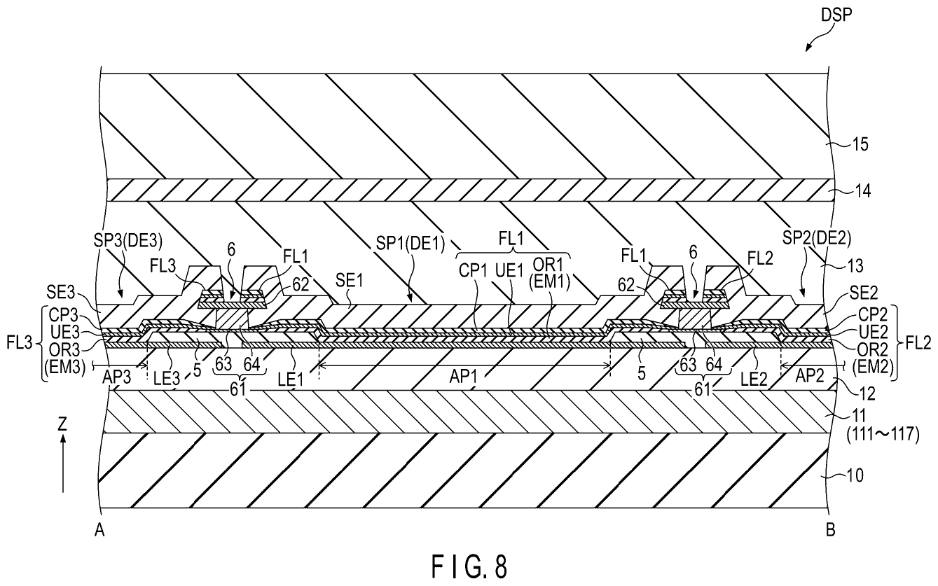

FIG. 8 is a schematic cross-sectional view of the display device DSP along the A-B line of FIG. 7. A circuit layer 11 is provided on the substrate 10. The circuit layer 11 includes various circuits such as the pixel circuit 1 shown in FIG. 1 and various lines such as the scanning line GL, the signal line SL and the power line PL. The circuit layer 11 includes insulating layers 111, 112, 113, 114, 115, 116 and 117 as described later. The circuit layer 11 is covered with an insulating layer 12. The insulating layer 12 is provided on the insulating layer 116 or insulating layer 117 of the circuit layer 11 and is an organic insulating layer which planarizes the irregularities formed by the circuit layer 11.

The lower electrodes LE1, LE2 and LE3 are provided on the insulating layer 12 and are spaced apart from each other. The insulating layer 5 is an inorganic insulating layer and is provided on the insulating layer 12 and the lower electrodes LE1, LE2 and LE3. The aperture AP1 of the insulating layer 5 overlaps the lower electrode LE1. The aperture AP2 overlaps the lower electrode LE2. The aperture AP3 overlaps the lower electrode LE3. The peripheral portions of the lower electrodes LE1, LE2 and LE3 are covered with the insulating layer 5. The lower electrodes LE1, LE2 and LE3 are connected to the pixel circuits 1 of subpixels SP1, SP2 and SP3, respectively, through contact holes provided in the insulating layer 12. The contact holes of the insulating layer 12 are omitted in FIG. 8.

The partition 6 includes a conductive lower portion 61 provided on the insulating layer 5 and an upper portion 62 provided on the lower portion 61. The upper portion 62 has a width greater than that of the lower portion 61. The both end portions of the upper portion 62 protrude relative to the side surfaces of the lower portion 61. This shape of the partition 6 is called an overhang shape.

In the example shown in the figure, the lower portion 61 has a bottom layer 63 provided on the insulating layer 5, and a stem layer 64 provided on the bottom layer 63. For example, the bottom layer 63 is formed so as to be thinner than the stem layer 64. In the example shown in the figure, the both end portions of the bottom layer 63 protrude from the side surfaces of the stem layer 64.

The organic layer OR1 is in contact with the lower electrode LE1 through the aperture AP1 and covers the lower electrode LE1 exposed from the aperture AP1. The peripheral portion of the organic layer OR1 is located on the insulating layer 5. The upper electrode UE1 covers the organic layer OR1 and is in contact with the lower portion 61.

The organic layer OR2 is in contact with the lower electrode LE2 through the aperture AP2 and covers the lower electrode LE2 exposed from the aperture AP2. The peripheral portion of the organic layer OR2 is located on the insulating layer 5. The upper electrode UE2 covers the organic layer OR2 and is in contact with the lower portion 61.

The organic layer OR3 is in contact with the lower electrode LE3 through the aperture AP3 and covers the lower electrode LE3 exposed from the aperture AP3. The peripheral portion of the organic layer OR3 is located on the insulating layer 5. The upper electrode UE3 covers the organic layer OR3 and is in contact with the lower portion 61.

In the example shown in the figure, subpixel SP1 has a cap layer CP1 and a sealing layer SE1. Subpixel SP2 has a cap layer CP2 and a sealing layer SE2. Subpixel SP3 has a cap layer CP3 and a sealing layer SE3. The cap layers CP1, CP2 and CP3 function as optical adjustment layers which improve the extraction efficiency of the light emitted from the organic layers OR1, OR2 and OR3, respectively. It should be noted that the cap layers CP1, CP2 and CP3 may be omitted.

The cap layer CP1 is provided on the upper electrode UE1.

The cap layer CP2 is provided on the upper electrode UE2.

The cap layer CP3 is provided on the upper electrode UE3.

The sealing layer SE1 is provided on the cap layer CP1, is in contact with the partition 6 and continuously covers the members of subpixel SP1.

The sealing layer SE2 is provided on the cap layer CP2, is in contact with the partition 6 and continuously covers the members of subpixel SP2.

The sealing layer SE3 is provided on the cap layer CP3, is in contact with the partition 6 and continuously covers the members of subpixel SP3.

In the example shown in the figure, each of the organic layer OR1, the upper electrode UE1 and the cap layer CP1 is partly located on the partition 6 around subpixel SP1. These portions are spaced apart from, of the organic layer OR1, the upper electrode UE1 and the cap layer CP1, the portions located in the aperture AP1 (the portions constituting the display element DE1).

Similarly, each of the organic layer OR2, the upper electrode UE2 and the cap layer CP2 is partly located on the partition 6 around subpixel SP2. These portions are spaced apart from, of the organic layer OR2, the upper electrode UE2 and the cap layer CP2, the portions located in the aperture AP2 (the portions constituting the display element DE2).

Similarly, each of the organic layer OR3, the upper electrode UE3 and the cap layer CP3 is partly located on the partition 6 around subpixel SP3. These portions are spaced apart from, of the organic layer OR3, the upper electrode UE3 and the cap layer CP3, the portions located in the aperture AP3 (the portions constituting the display element DE3).

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

The end portions of the sealing layers SE1, SE2 and SE3 and the end portions of the stacked films FL1, FL2 and FL3 are located on the partition 6. In the example shown in the figure, the stacked film FL1 and sealing layer SE1 located on the partition 6 between subpixels SP1 and SP2 are spaced apart from the stacked film FL2 and sealing layer SE2 located on this partition 6. The stacked film FL1 and sealing layer SE1 located on the partition 6 between subpixels SP1 and SP3 are spaced apart from the stacked film FL3 and sealing layer SE3 located on this partition 6.

The sealing layers SE1, SE2 and SE3 are covered with a resin layer 13. The resin layer 13 is covered with a sealing layer 14. The sealing layer 14 is covered with a resin layer 15.

Each of the insulating layer 5, the sealing layers SE1, SE2 and SE3 and the sealing layer 14 is formed of, for example, an inorganic insulating material such as silicon nitride (SiNx), silicon oxide (Siox), silicon oxynitride (SiON) or aluminum oxide (Al₂O₃).

The lower portion 61 of the partition 6 is formed of a conductive material and is electrically connected to the upper electrodes UE1, UE2 and UE3. The upper portion 62 of the partition 6 is formed of, for example, a conductive material. However, the upper portion 62 may be formed of an insulating material. The lower portion 61 is formed of a material which is different from that of the upper portion 62.

Each of the lower electrodes LE1, LE2 and LE3 is a multilayer body including a transparent electrode formed of an oxide conductive material such as indium tin oxide (ITO) and a metal electrode formed of a metal material such as silver. For example, each of the lower electrodes LE1, LE2 and LE3 is a multilayer body including a metal electrode between a pair of transparent electrodes.

The organic layer OR1 includes a light emitting layer EM1. The organic layer OR2 includes a light emitting layer EM2. The organic layer OR3 includes a light emitting layer EM3. The light emitting layer EM1, the light emitting layer EM2 and the light emitting layer EM3 are formed of materials which are different from each other. For example, the light emitting layer EM1 is formed of a material which emits light in a blue wavelength range. The light emitting layer EM2 is formed of a material which emits light in a green wavelength range. The light emitting layer EM3 is formed of a material which emits light in a red wavelength range.

Each of the organic layers OR1, OR2 and OR3 includes a plurality of functional layers such as a hole injection layer, a hole transport layer, an electron blocking layer, a hole blocking layer, an electron transport layer and an electron injection layer.

Each of the upper electrodes UE1, UE2 and UE3 is formed of, for example, a metal material such as an alloy of magnesium and silver (MgAg).

Each of the cap layers CP1, CP2 and CP3 is a multilayer body consisting of a plurality of thin films. All of the thin films are transparent and have refractive indices different from each other.

The circuit layer 11, insulating layer 12, insulating layer 5, resin layer 13, resin layer 15 and sealing layer 14 shown in the figure are provided over the display area DA and the surrounding area SA.

Now, this specification explains an example of the shape of the partition 7 intersecting with the belt-like area BA.

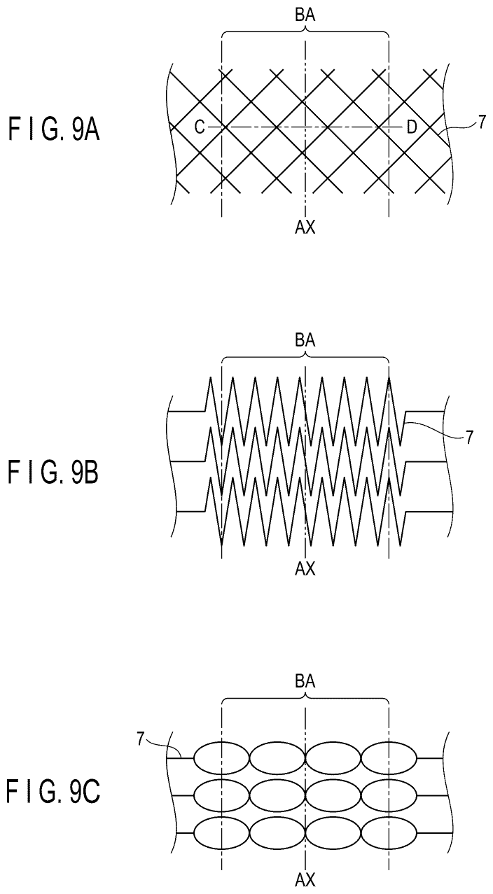

FIG. 9A is a plan view showing an example of the shape of the partition 7.

The partition 7 is formed into a grating shape in plan view. Each portion which forms closed loops in the partition 7 extends so as to intersect with axis AX of the belt-like area BA. Thus, when the belt-like area BA is curved, the partition 7 is easily elongated, and the break of the partition 7 can be prevented. In addition, as the partition 7 is formed into a grating shape, even if part of the partition 7 is broken, conduction can be assured in the other portions.

FIG. 9B is a plan view showing another example of the shape of the partition 7.

The partition 7 is formed into the shape of broken lines in plan view. Each linear component of the partition 7 extends so as to intersect with axis AX of the belt-like area BA. Thus, when the belt-like area BA is curved, the partition 7 is easily elongated, and the break of the partition 7 can be prevented.

FIG. 9C is a plan view showing another example of the shape of the partition 7.

The partition 7 has a plurality of annular portions which are connected to each other in a direction intersecting with axis AX. Each annular portion is formed into an oval shape or elliptic shape which extends in a direction intersecting with axis AX. Thus, when the belt-like area BA is curved, the partition 7 is easily elongated, and the break of the partition 7 can be prevented.

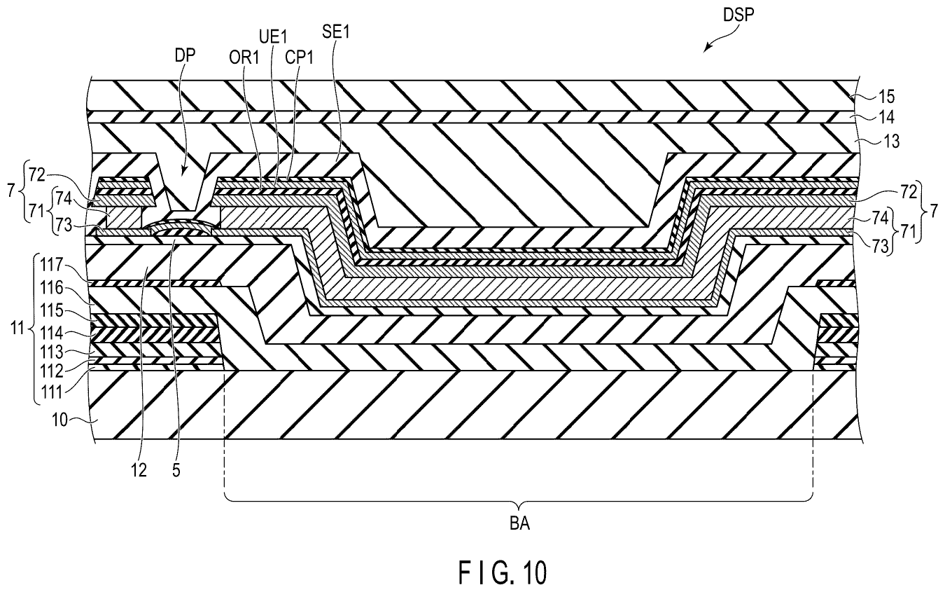

FIG. 10 is a cross-sectional view of the display device DSP along the partition 7 intersecting with the belt-like area BA.

The circuit layer 11 provided on the substrate 10 includes a plurality of insulating layers such as the insulating layers 111, 112, 113, 114, 115, 116 and 117.

The insulating layer 111 is an inorganic insulating layer and is provided on the substrate 10. The insulating layer 112 is an inorganic insulating layer and is provided on the insulating layer 111. The insulating layer 113 is an inorganic insulating layer and is provided on the insulating layer 112. The insulating layer 114 is an inorganic insulating layer and is provided on the insulating layer 113. The insulating layer 115 is an inorganic insulating layer and is provided on the insulating layer 114.

The insulating layer 116 is an organic insulating layer and is provided on the insulating layer 115. In the example shown in the figure, the insulating layer 116 is in contact with the substrate 10 in the belt-like area BA.

The insulating layer 117 is an inorganic insulating layer and is provided on the insulating layer 116.

The belt-like area BA corresponds to an area in which at least one of these insulating layers 111 to 117 is lost in a belt-like shape. For example, in the example shown in FIG. 1, at least one of the insulating layers 111 to 117 is lost in a belt-like shape in the second direction Y such that the belt-like areas BA are formed. In the example shown in FIG. 3, at least one of the insulating layers 111 to 117 is lost in a belt-like shape in the first direction X such that the belt-like area BA is formed.

In the example shown in FIG. 10, the insulating layers 111 to 115 and 117 which are inorganic insulating layers are lost in the belt-like area BA. It should be noted that the insulating layer 116 which is an organic insulating layer may be lost in the belt-like area BA. To prevent cracks in the insulating layers when the belt-like area BA is curved, it is preferable that all of the inorganic insulating layers included in the circuit layer 11 should be lost.

The insulating layer 12 is an organic insulating layer as described above, and is provided on the insulating layer 116 and the insulating layer 117. In the example shown in the figure, the insulating layer 12 is in contact with the insulating layer 116 in the belt-like area BA.

The insulating layer 5 is an inorganic insulating layer as described above, and is provided on the insulating layer 12. The insulating layer 5 is provided in the belt-like area BA as well. In a dummy pixel DP located on the external side of the belt-like area BA (or between the belt-like area BA and the display area), the insulating layer 5 does not have any aperture and covers the insulating layer 12.

The partition 7 includes a conductive lower portion 71 provided on the insulating layer 5 and an upper portion 72 provided on the lower portion 71. The upper portion 72 has a width which is greater than that of the lower portion 71. The both end portions of the upper portion 72 protrude relative to the side surfaces of the lower portion 71. The dummy pixel DP is surrounded by the partition 7.

In the example shown in the figure, the lower portion 71 has a bottom layer 73 provided on the insulating layer 5, and a stem layer 74 provided on the bottom layer 73. For example, the bottom layer 73 is formed so as to be thinner than the stem layer 74. In the example shown in the figure, the both end portions of the bottom layer 73 protrude from the side surfaces of the stem layer 74.

This partition 7 can be formed in a manner similar to that of the partition 6 of the display area DA. In other words, the lower portion 61 and the lower portion 71 are formed of the same material, and the upper portion 62 and the upper portion 72 are formed of the same material.

The organic layer OR1 is provided on the partition 7 and is provided on the insulating layer 5 in the dummy pixel DP surrounded by the partition 7. The upper electrode UE1 is provided on the organic layer OR1 immediately above the partition 7, is provided on the organic layer OR1 in the dummy pixel DP and is in contact with the lower portion 71. The cap layer CP1 is provided on the upper electrode UE1 immediately above the partition 7 and is provided on the upper electrode UE1 in the dummy pixel DP. The sealing layer SE1 continuously covers the cap layer CP1 and the partition 7. The sealing layer SE1 is covered with the resin layer 13. The resin layer 13 is covered with the sealing layer 14. The sealing layer 14 is covered with the resin layer 15.

FIG. 11 is a cross-sectional view of the display device DSP along the C-D line of FIG. 9. The partition 7 is provided in the belt-like area BA. In the belt-like area BA, the organic layer OR1 including the light emitting layer is provided on the partition 7 and the insulating layer 5. The upper electrode UE1 is provided on the organic layer OR1 and is in contact with the partition 7. The cap layer CP1 is provided on the upper electrode UE1. The organic layer OR1, upper electrode UE1 and cap layer CP1 surrounded by the partition 7 are spaced apart from the organic layer OR1, upper electrode UE1 and cap layer CP1 provided on the partition 7. The sealing layer SE1 is provided on the cap layer CP1 and continuously covers the cap layer CP1 and the partition 7 around the cap layer CP1.

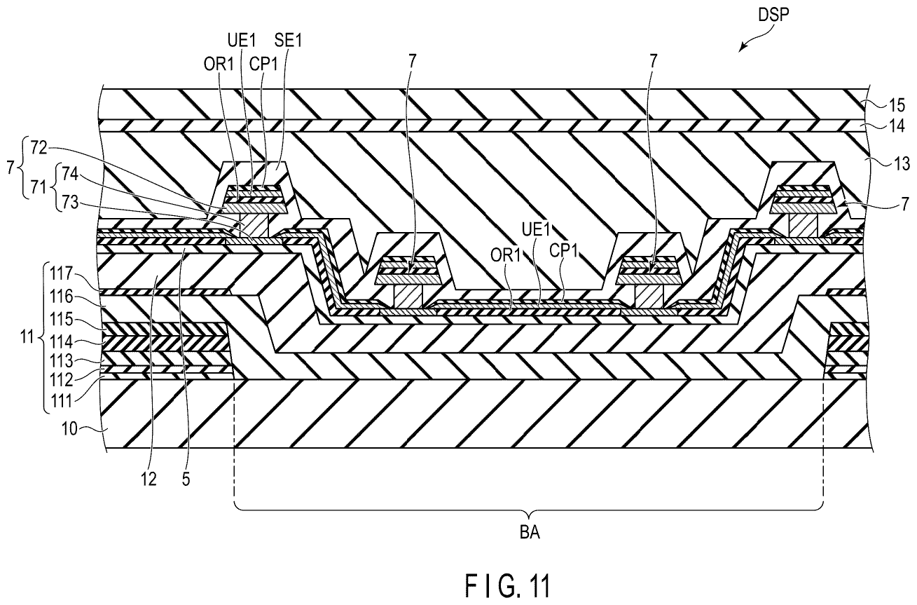

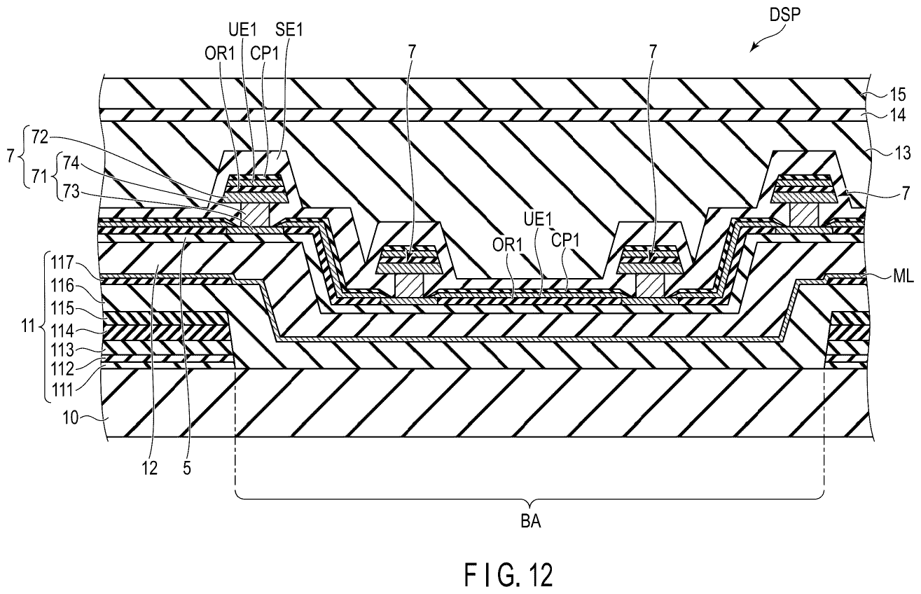

FIG. 12 is a cross-sectional view of the display device DSP including a metal line ML intersecting with the belt-like area BA

The circuit layer 11 includes the metal line ML. This metal line ML is, for example, a line which electrically connects the various lines of the display area DA and the terminals TE to each other. The metal line ML is provided on the insulating layer 117 and is provided on the insulating layer 116 in the belt-like area BA. This metal line ML is covered with the insulating layer 12. Thus, the metal line ML is provided between the insulating layer 116 and the insulating layer 12 in the belt-like area BA. As described above, the insulating layer 116 and the insulating layer 12 are organic insulating layers which are more flexible than inorganic insulating layers. Therefore, even when the belt-like area BA is curved, the break of the metal line ML can be prevented.

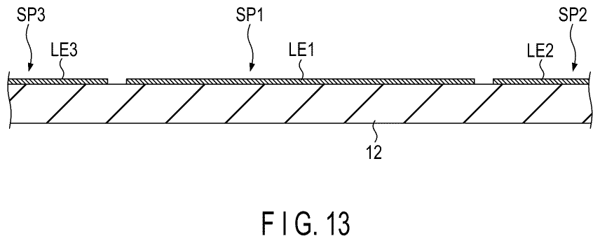

Now, this specification explains the manufacturing method of the display device DSP. Regarding FIG. 13 to FIG. 19, the illustration of the lower side of the insulating layer 12 is omitted.

First, the circuit layer 11 and the insulating layer 12 are formed on the substrate 10 over the display area DA and the surrounding area SA. Subsequently, as shown in FIG. 13, the lower electrode LE1 of subpixel SP1, the lower electrode LE2 of subpixel SP2 and the lower electrode LE3 of subpixel SP3 are formed on the insulating layer 12. The process of forming the lower electrodes LE1, LE2 and LE3 includes, for example, the following steps. An ITO layer is formed on the insulating layer 12. A silver layer is formed on the ITO layer. An ITO layer is formed on the silver layer. Subsequently, the ITO layer, the silver layer and the ITO layer are patterned. By this process, the lower electrodes LE1, LE2 and LE3 are formed. In the process of forming the circuit layer 11, the belt-like area BA shown in FIG. 10 etc., is also formed.

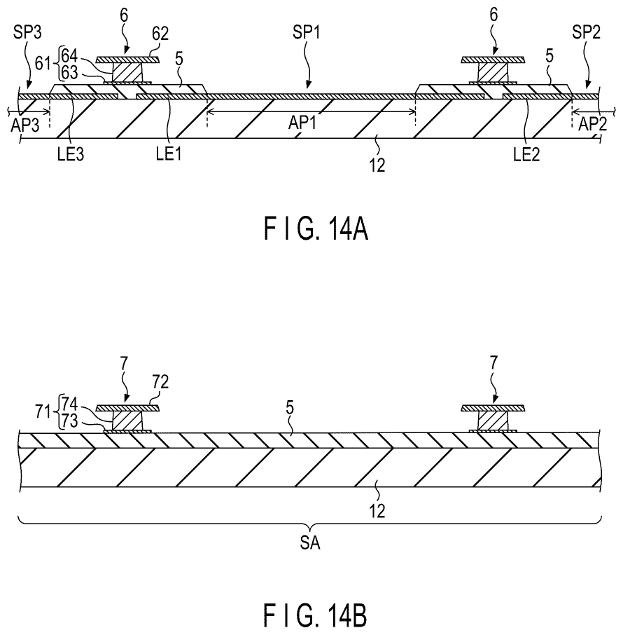

Subsequently, as shown in FIG. 14A, the insulating layer 5 is formed over the display area DA and the surrounding area SA. Subsequently, the partition 6 which comprises the lower portion 61 located on the insulating layer 5 and the upper portion 62 located on the lower portion 61 is formed. Subsequently, the apertures AP1, AP2 and AP3 are formed in the insulating layer 5. The aperture AP1 overlaps the lower electrode LE1 of subpixel SP1. The aperture AP2 overlaps the lower electrode LE2 of subpixel SP2. The aperture AP3 overlaps the lower electrode LE3 of subpixel SP3. It should be noted that the formation process of the apertures AP1, AP2 and AP3 may be performed before the formation process of the partition 6.

At this time, as shown in FIG. 14B, the partition 7 which comprises the lower portion 71 located on the insulating layer 5 and the upper portion 72 located on the lower portion 71 is formed in the belt-like area BA. The lower portion 71 is formed at the same time as the lower portion 61. The upper portion 72 is formed at the same time as the upper portion 62. No aperture is formed in the insulating layer 5 in the belt-like area BA.

Subsequently, the display element DE1 is formed in the display area DA.

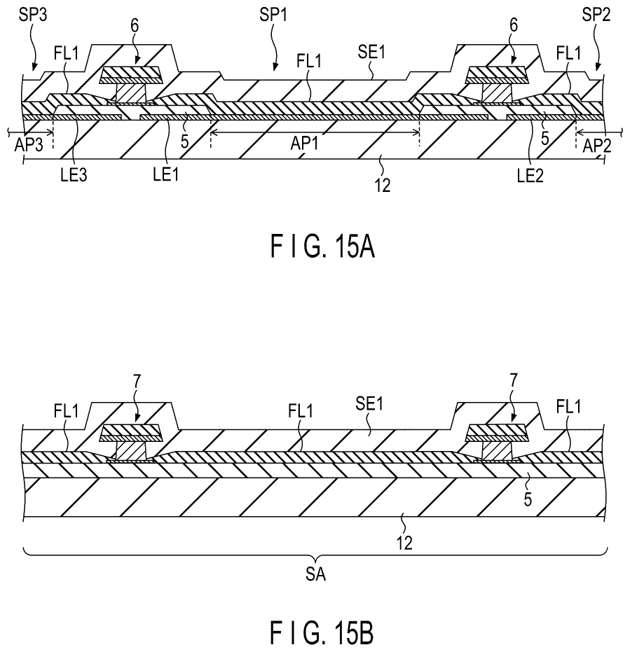

First, as shown in FIG. 15A, the stacked film FL1 is formed. The stacked film FL1 includes the organic layer OR1 which is in contact with the lower electrode LE1 through the pixel aperture AP1, the upper electrode UE1 which covers the organic layer OR1 and is in contact with the lower portion 61 of the partition 6, and the cap layer CP1 located on the upper electrode UE1. The organic layer OR1 includes a hole injection layer, a hole transport layer, an electron blocking layer, the light emitting layer EM1, a hole blocking layer, an electron transport layer, an electron injection layer and the like. Each of the organic layer OR1, the upper electrode UE1 and the cap layer CP1 is formed by vapor deposition using the partition 6 as a mask. The stacked film FL1 is divided into a plurality of portions by the partition 6 having an overhang shape. These organic layer OR1, upper electrode UE1 and cap layer CP1 are continuously formed while maintaining a vacuum environment.

Subsequently, the sealing layer SE1 is formed on the stacked film FL1. The sealing layer SE1 is formed by chemical vapor deposition (CVD). The sealing layer SE1 continuously covers the portions into which the stacked film FL1 is divided, and the partition 6.

At this time, the stacked film FL1 is formed in the belt-like area BA as well as shown in FIG. 15B. The process of forming the stacked film FL1 includes the process of forming the organic layer OR1 including the light emitting layer EM1 on the partition 7 and the insulating layer 5, the process of forming the upper electrode UE1 which covers the organic layer OR1 and is in contact with the lower portion 71 of the partition 7, and the process of forming the cap layer CP1 on the upper electrode UE1. Each of the organic layer OR1, the upper electrode UE1 and the cap layer CP1 is formed by vapor deposition using the partition 7 as a mask. In the belt-like area BA, similarly, the stacked film FL1 is divided into a plurality of portions by the partition 7 having an overhang shape.

Subsequently, the sealing layer SE1 is formed on the stacked film FL1. The sealing layer SE1 is formed by CVD. The sealing layer SE1 continuously covers the portions into which the stacked film FL1 is divided, and the partition 7.

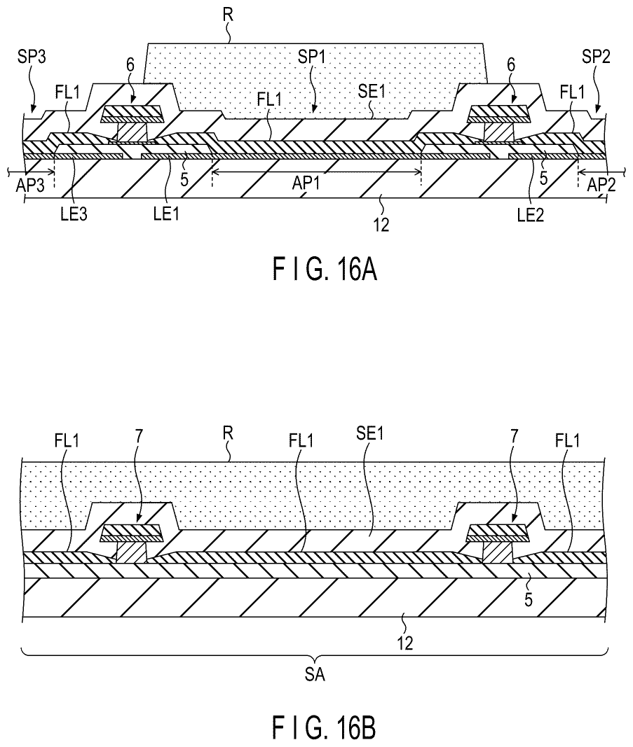

Subsequently, as shown in FIG. 16A, a resist R patterned into a predetermined shape is formed on the sealing layer SE1. The resist R overlaps subpixel SP1 and part of the partition 6 around subpixel SP1.

At this time, as shown in FIG. 16B, the sealing layer SE1 is covered with the resist R in the belt-like area BA.

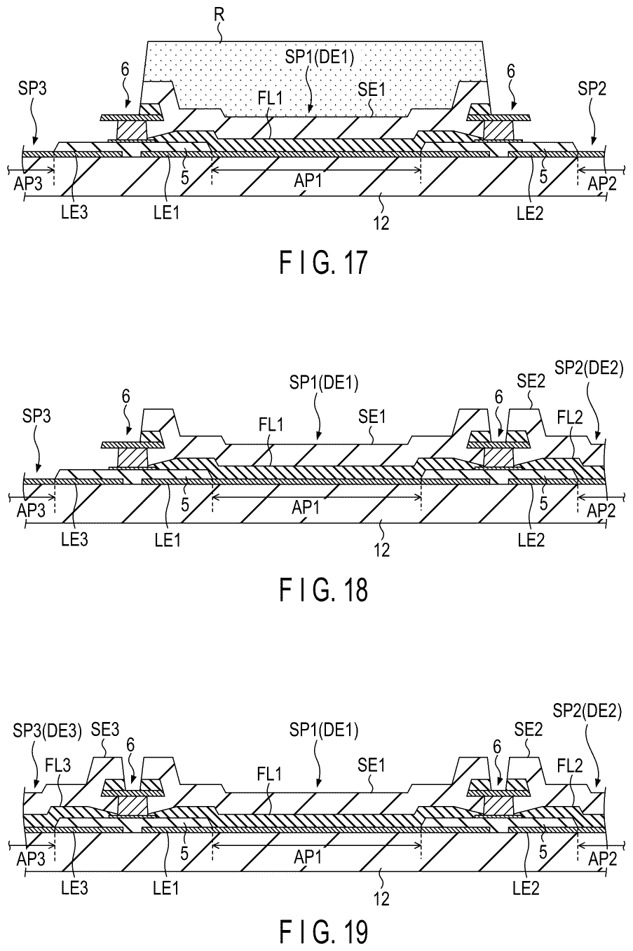

Subsequently, as shown in FIG. 17, etching is performed using the resist R as a mask. By this process, the sealing layer SE1 and stacked film FL1 exposed form the resist R are removed. In this etching, the sealing layer SE1 exposed from the resist R, the cap layer CP1 exposed from the sealing layer SE1, the upper electrode UE1 exposed from the cap layer CP1 and the organic layer OR1 exposed from the upper electrode UE1 are removed in series. In this manner, the lower electrode LE2 of subpixel SP2 and the lower electrode LE3 of subpixel SP3 are exposed.

Subsequently, the resist R is removed. By this process, the display element DE1 is formed in subpixel SP1.

Subsequently, as shown in FIG. 18, the display element DE2 is formed. The procedure of forming the display element DE2 is similar to that of forming the display element DE1. Specifically, the stacked film FL2 is formed by forming the organic layer OR2 including the light emitting layer EM2, the upper electrode UE2 and the cap layer CP2 in order on the lower electrode LE2. Subsequently, the sealing layer SE2 is formed on the stacked film FL2. Subsequently, a resist is formed on the sealing layer SE2. The sealing layer SE2, the cap layer CP2, the upper electrode UE2 and the organic layer OR2 are patterned by etching using the resist as a mask. After this patterning, the resist is removed. In this manner, the display element DE2 is formed in subpixel SP2, and the lower electrode LE3 of subpixel SP3 is exposed.

Subsequently, as shown in FIG. 19, the display element DE3 is formed. The procedure of forming the display element DE3 is similar to that of forming the display element DE1. Specifically, the stacked film FL3 is formed by forming the organic layer OR3 including the light emitting layer EM3, the upper electrode UE3 and the cap layer CP3 in order on the lower electrode LE3. Subsequently, the sealing layer SE3 is formed on the stacked film FL3. Subsequently, a resist is formed on the sealing layer SE3. The sealing layer SE3, the cap layer CP3, the upper electrode UE3 and the organic layer OR3 are patterned by etching using the resist as a mask. After this patterning, the resist is removed. By this process, the display element DE3 is formed in subpixel SP3.

Subsequently, the resin layer 13, sealing layer 14 and resin layer 15 shown in FIG. 8 and the like are formed in order. By this process, the display device DSP is completed.

In the manufacturing process described above, this specification assumes a case where the display element DE1 is formed firstly, and the display element DE2 is formed secondly, and the display element DE3 is formed lastly. However, the formation order of the display elements DE1, DE2 and DE3 is not limited to this example.

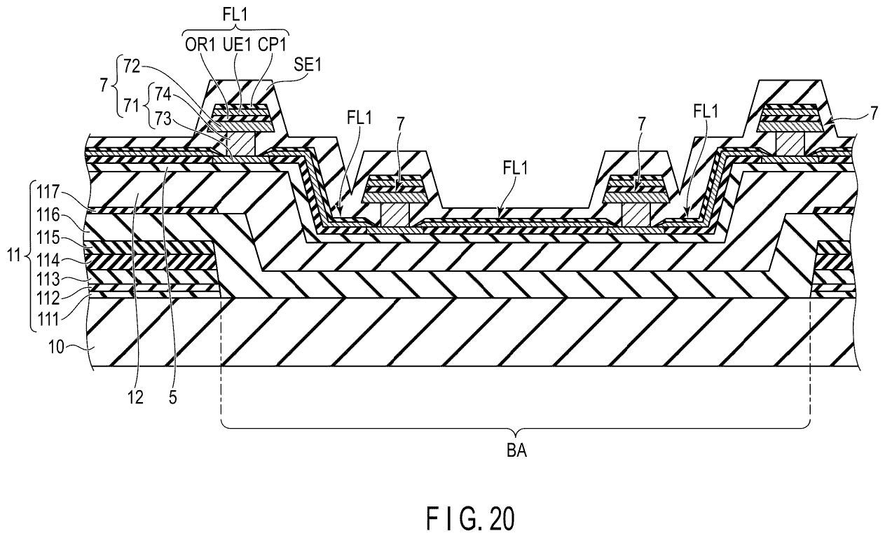

FIG. 20 is a cross-sectional view for explaining a state in which the stacked film FL1 is formed in the belt-like area BA.

Here, the stacked film FL1 includes the organic layer OR1, the upper electrode UE1 and the cap layer CP1 for forming the display element DE1. The stacked film FL1 is formed on the insulating layer 5 and the partition 7. The partition 7 is provided on the insulating layer 5 and is covered with the sealing layer SE1 with the stacked film FL1.

In this manner, the insulating layer 5 is pressed by the partition 7 and the sealing layer SE1, and thus, the lift of the insulating layer 5 from the insulating layer 12 is prevented.

The stacked film FL1 is divided into a plurality of portions by the partition 7. For this reason, compared to a case where the stacked film FL1 is not divided, the area of the continuous stacked film FL1 is reduced, and a stress which could be generated in the stacked film FL1 is dispersed. In addition, the stacked film FL1 is pressed by the partition 7 and the sealing layer SE1. Thus, the lift of the stacked film FL1 from the insulating layer 5 is prevented.

Therefore, the separation of the insulating layer 5 from the insulating layer 12 and the separation of the stacked film FL1 from the insulating layer 5 can be prevented.

Here, this specification explains problems which could occur when the insulating layer 5 and the stacked film FL1 are separated. The separated insulating layer 5 and stacked film FL1 could float inside the manufacturing device as foreign substances and could be a contaminant source. If the floating foreign substances are attached to the processing substrate, various defects may be caused.

In the embodiment, although a relatively large step is formed in the belt-like area BA where the insulating layer included in the circuit layer 11 is lost, the separation of the insulating layer 5 and the stacked film FL1 can be prevented by the configuration described above. This configuration prevents the contamination of the manufacturing device and the generation of undesired foreign substances. Moreover, even when the belt-like area BA is curved, the separation of the insulating layer 5 and the stacked film FL1 can be prevented. In this manner, the reduction in reliability is prevented.

In the embodiment described above, for example, the insulating layer 5 corresponds to a first inorganic insulating layer. Each of the insulating layers 111 to 115 corresponds to a second inorganic insulating layer. The insulating layer 12 corresponds to a first organic insulating layer. The insulating layer 116 corresponds to a second organic insulating layer. The partition 7 corresponds to a first partition. The lower portion 71 corresponds to a first lower portion. The upper portion 72 corresponds to a first upper portion. The partition 6 corresponds to a second partition. The lower portion 61 corresponds to a second lower portion. The upper portion 62 corresponds to a second upper portion.

As explained above, the present embodiment can provide a display device and a manufacturing method thereof such that the reduction in reliability can be prevented.

All of the display devices and manufacturing methods thereof that can be implemented by a person of ordinary skill in the art through arbitrary design changes to the display device and manufacturing method thereof described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A display device comprising:
a resinous substrate having flexibility;
a circuit layer including a plurality of insulating layers provided over a display area which displays an image and a surrounding area located on an external side relative to the display area on the resinous substrate;
a first organic insulating layer provided over the display area and the surrounding area on the circuit layer;
a first inorganic insulating layer provided over the display area and the surrounding area on the first organic insulating layer; and
a first partition comprising a first lower portion provided on the first inorganic insulating layer and a first upper portion which is provided on the first lower portion and protrudes from a side surface of the first lower portion in the surrounding area, wherein
the circuit layer has a belt-like area in which at least one of the plurality of insulating layers is lost in a belt-like shape, and
the first partition is provided in the belt-like area.

2. The display device of claim 1, wherein
the first partition is provided so as to intersect with the belt-like area.

3. The display device of claim 1, wherein
the first lower portion is formed of a conductive material, and is electrically connected to a terminal having a common potential.

4. The display device of claim 1, wherein
the circuit layer includes a second organic insulating layer, and
the first organic insulating layer and the second organic insulating layer are in contact with each other in the belt-like area.

5. The display device of claim 4, wherein
the plurality of insulating layers include a plurality of second inorganic insulating layers provided between the resinous substrate and the second organic insulating layer, and
at least one of the second inorganic insulating layers is lost in a belt-like shape in the belt-like area.

6. The display device of claim 5, wherein
the resinous substrate and the second organic insulating layer are in contact with each other in the belt-like area.

7. The display device of claim 1, wherein
the circuit layer includes a metal line and a second organic insulating layer, and
the metal line is provided between the first organic insulating layer and the second organic insulating layer in the belt-like area.

8. The display device of claim 1, further comprising:
an organic layer which is provided on the first partition and the first inorganic insulating layer in the belt-like area and includes a light emitting layer; and
an upper electrode provided on the organic layer, wherein
the organic layer and the upper electrode are surrounded by the first partition in plan view, and
the upper electrode is in contact with the first partition.

9. The display device of claim 8, further comprising:
a cap layer provided on the upper electrode; and
a sealing layer which is formed of an inorganic insulating material and covers the cap layer and the first partition.

10. The display device of claim 1, further comprising:
a lower electrode provided on the first organic insulating layer and overlapping an aperture of the first inorganic insulating layer in the display area;
an organic layer which is provided on the lower electrode in the aperture and includes a light emitting layer; and
an upper electrode provided on the organic layer.

11. The display device of claim 10, further comprising
a second partition comprising a second lower portion which is provided on the first inorganic insulating layer and is formed of a conductive material and a second upper portion which is provided on the second lower portion and protrudes from a side surface of the second lower portion in the display area, wherein
the lower electrode, the organic layer and the upper electrode are surrounded by the second partition in plan view, and
the upper electrode is in contact with the second partition.

12. The display device of claim 11, further comprising:
a cap layer provided on the upper electrode; and
a sealing layer which is formed of an inorganic insulating material and covers the cap layer and the second partition.

13. The display device of claim 11, wherein
the first lower portion and the second lower portion are formed of a same material, and
the first upper portion and the second upper portion are formed of a same material.

14. A display device comprising
a display panel which comprises a display area displaying an image and a surrounding area located on an external side relative to the display area and is bent in a belt-like area, wherein
the display panel comprises:
a resinous substrate having flexibility;
a first organic insulating layer provided over the display area and the surrounding area above the resinous substrate;
a first inorganic insulating layer provided over the display area and the surrounding area on the first organic insulating layer; and
a first partition comprising a first lower portion provided on the first inorganic insulating layer and a first upper portion which is provided on the first lower portion and protrudes from a side surface of the first lower portion in the belt-like area.

15. The display device of claim 14, wherein
the belt-like area is located in the surrounding area.

16. The display device of claim 14, wherein
the belt-like area intersects with the display area.

17. A manufacturing method of a display device, the method comprising:
forming a circuit layer including a plurality of insulating layers over a display area which displays an image and a surrounding area located on an external side relative to the display area on a resinous substrate having flexibility;
forming a first organic insulating layer over the display area and the surrounding area on the circuit layer;
forming a first inorganic insulating layer over the display area and the surrounding area on the first organic insulating layer; and
forming a first partition comprising a first lower portion located on the first inorganic insulating layer and a first upper portion which is located on the first lower portion and protrudes from a side surface of the first lower portion in the surrounding area, wherein
the circuit layer has a belt-like area in which at least one of the plurality of insulating layers is lost in a belt-like shape, and
the first partition is located in the belt-like area.

18. The manufacturing method of claim 17, further comprising, after forming the first partition,
forming an organic layer which includes a light-emitting layer on the first partition and the first inorganic insulating layer, and
forming an upper electrode on the organic layer, wherein
each of the organic layer and the upper electrode is formed by vapor deposition using the first partition as a mask.

19. The manufacturing method of claim 18, further comprising, after forming the upper electrode,
forming a cap layer on the upper electrode by performing vapor deposition using the first partition as a mask, and
forming a sealing layer which covers the cap layer and the first partition by using an inorganic insulating material.

20. The manufacturing method of claim 19, further comprising, after forming the sealing layer,
forming a patterned resist on the sealing layer, and
removing part of the sealing layer, part of the cap layer, part of the upper electrode and part of the organic layer in series in the display area by performing etching using the resist as a mask, wherein
the sealing layer is covered with the resist in the belt-like area.
